(19) United States
(12) Patent Application Publication
(10) Pub. No.: US 2006/0024879 A1
(43) Pub. Date: Feb. 2, 2006

(54) Selectively strained MOSFETs to improve drive current

(75) Inventors: Chu-Yun Fu, Taipei (TW); Cheng-Hung Chang, Hsinchu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/902,973

(22) Filed: Jul. 31, 2004

(51) Int. Cl. H01L 21/8238; H01L 21/31

(52) U.S. Cl. 438/216; 438/791

(57) ABSTRACT

A MOSFET device pair with improved drive current and a method for producing the same to selectively introduce strain into a respective N-type and P-type MOSFET device channel region, the method including forming a compressive stressed nitride layer on over the P-type MOSFET device and a tensile stressed nitride layer on the N-type MOSFET device followed by forming a PMD layer having a less compressive or tensile stress.

### FIELD OF THE INVENTION

This invention generally relates to formation of MOSFET devices in integrated circuit manufacturing processes and more particularly to MOSFET devices and methods of forming the same to selectively provide strain-induced charge carrier band modification for enhanced charge carrier mobility and improved MOSFET device drive current.

### BACKGROUND OF THE INVENTION

Mechanical stresses are known to play a role in charge carrier mobility which affects drive current and Voltage threshold shifts. The effect of mechanical stresses is to induce a strain on a MOSFET channel region and thereby improve a MOSFET device drive current which is proportional to charge carrier mobility.

Generally, various manufacturing processes are known to introduce strain into the MOSFET device channel region. For example, strain may be introduced into the channel region by the use of selectively strained SiGe substrates. However, several integration problems inherent in SiGe processing technology as well as the cost of SiGe substrates remain issues limiting the cost-effective implementation of strained SiGe approaches to gain the benefits of strain-induced band modification.

Prior art processes have attempted to introduce offsetting stresses into the channel region by forming stressed dielectric layers over gate structures following a silicide formation process. These approaches have met with limited success, however, since the formation of the stressed dielectric layer of a particular type of stress e.g., tensile or compressive, has a degrading electrical performance effect on a CMOS device with an opposite type of polarity e.g., N vs. P majority charge carriers. For example, as NMOS device performance is improved by forming tensile stressed dielectric layers, PMOS device performance is typically degraded.

Other shortcomings in prior art approaches are the adverse affect of the dielectric stressed layers on subsequent gap filling ability of a subsequently deposited dielectric layers as well as associated thermal processing temperatures which detrimentally affect previously formed materials such as stressed dielectric layers and metal silicides. For example, typical processes of forming pre-metal dielectric (PMD) layers over stressed dielectric layers may lead to stress relaxation or thinning of stressed dielectric layers making device performance improvement, if any, unpredictable.

In addition, prior art processes in forming stressed dielectric layers have the limitation of requiring different processing tools for a given stress type, thereby increasing the cost of production and reducing throughput. In addition, prior art approaches of forming stressed dielectric layers have been limited by the range of stress levels that may be formed, typically depending primarily on thickness to achieve a desired stress level. When producing highly stressed dielectric layers, this approach has the offsetting effect of limiting a gap filling ability in a subsequent PMD layer deposition process thereby leading to the formation of voids, compromising device yield and reliability.

These and other shortcomings demonstrate a need in the semiconductor device integrated circuit manufacturing art for improved strained channel MOSFET devices and methods for forming the same to improve both NMOS and PMOS device performance, reliability, and yield.

It is therefore an object of the present invention to provide improved strained channel MOSFET devices and methods for forming the same to improve both NMOS and PMOS device performance, reliability, and yield, while overcoming other shortcomings of the prior art.

### SUMMARY OF THE INVENTION

To achieve the foregoing and other objects, and in accordance with the purposes of the present invention, as embodied and broadly described herein, the present invention provides a MOSFET device pair with improved drive current and a method for producing the same to selectively introduce strain into a respective N-type and P-type MOSFET device channel region.

In a first embodiment, the method includes providing a first and second MOSFET device having a respective first polarity and second polarity opposite from the first polarity selected from the group consisting of P and N type on a semiconducting substrate; forming a first stressed nitride layer having a first stress type selected from the group consisting of compressive and tensile stress over the first and second MOSFET device active areas; removing the first stressed nitride layer overlying the second MOSFET device active area; forming a second stressed nitride layer having a second stress type opposite the first stress type over the first and second MOSFET device active areas; removing the second stressed nitride layer overlying the first MOSFET device active area; and, forming a dielectric insulating layer over the first and second MOSFET device active areas having a less compressive or tensile stress.

These and other embodiments, aspects and features of the invention will be better understood from a detailed description of the preferred embodiments of the invention which are further described below in conjunction with the accompanying Figures.

BRIEF DESCRIPTION OF THE DRAWINGS

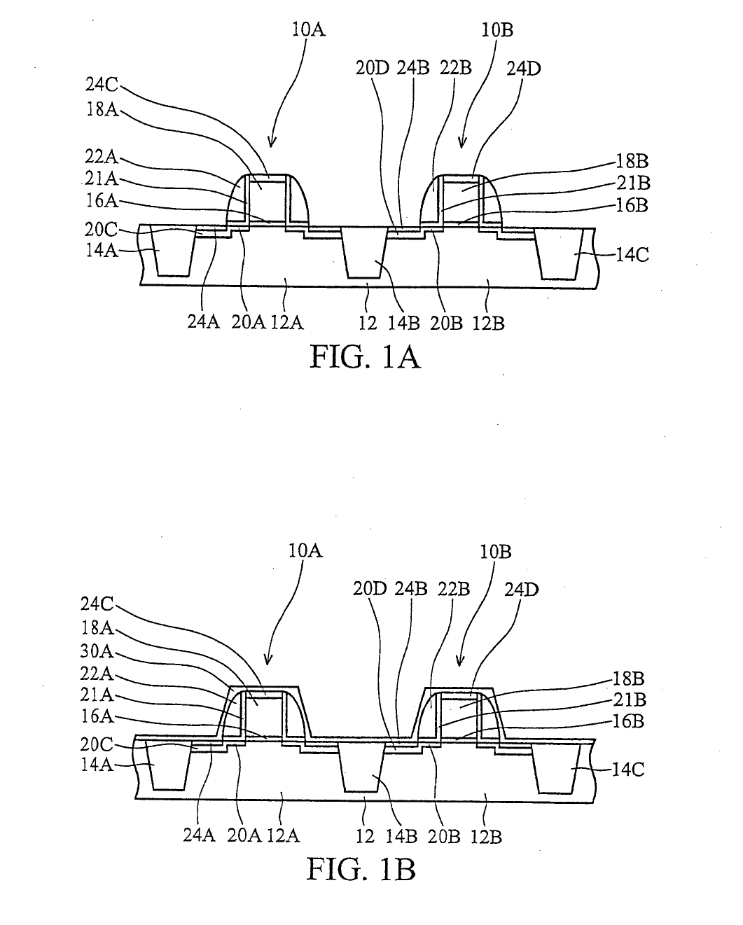

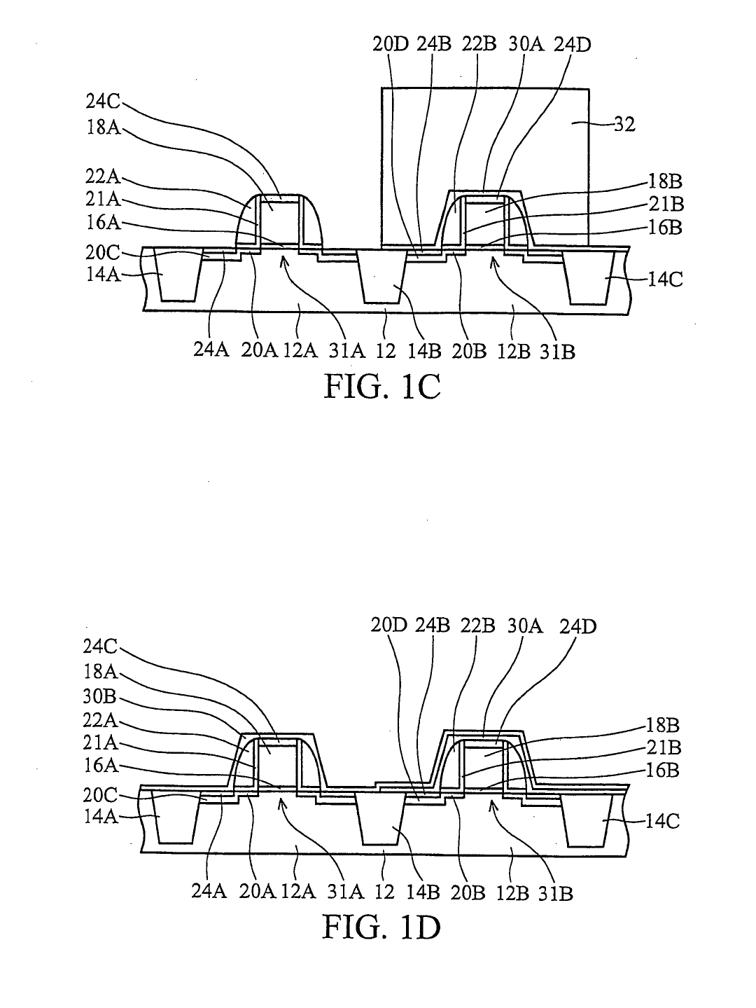

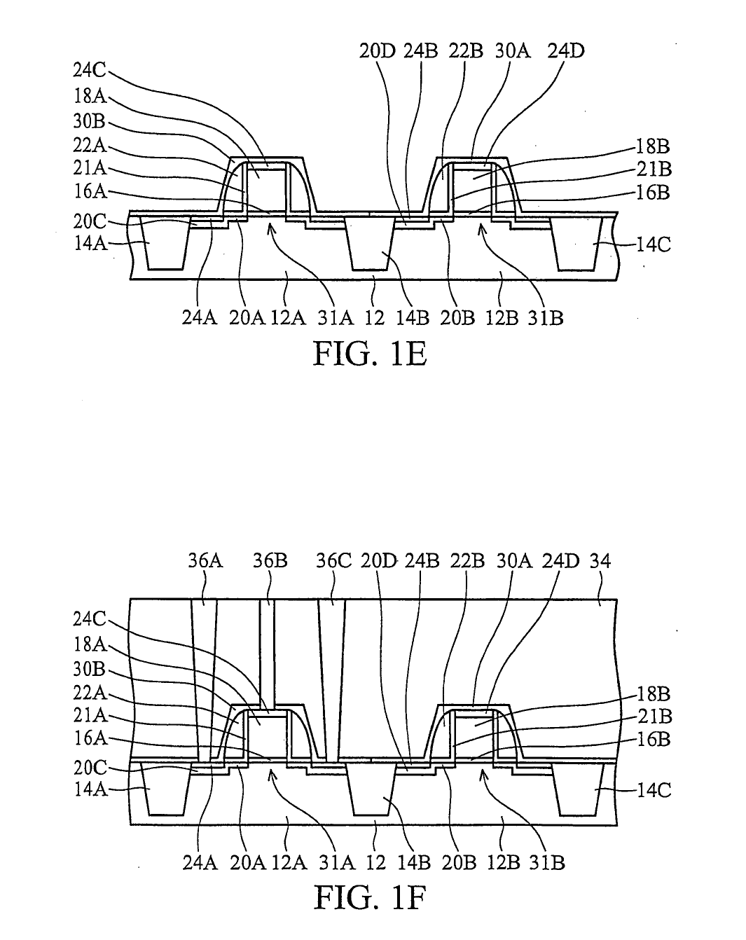

FIGS. 1A-1F are cross sectional schematic representations of exemplary portions of a MOSFET device pair including NMOS and PMOS portions formed at stages of manufacture according to an embodiment of the present invention.

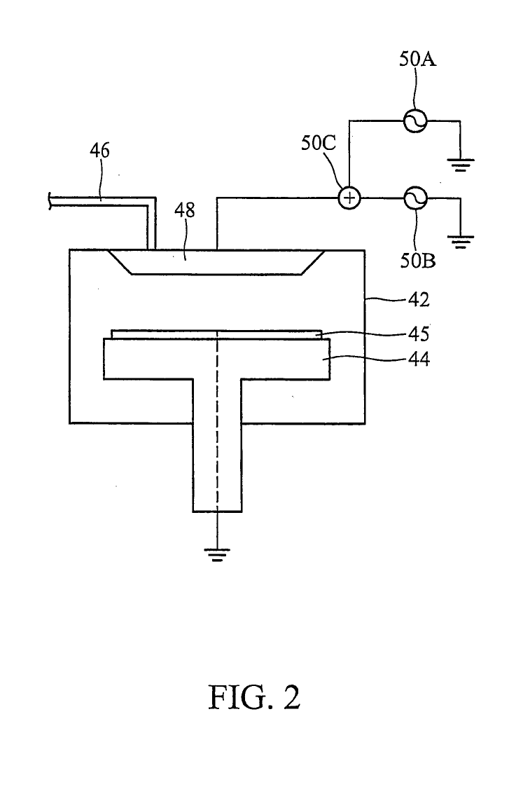

FIG. 2 is an exemplary mixed frequency RF power source PECVD reactor for implementing an embodiment of the present invention.

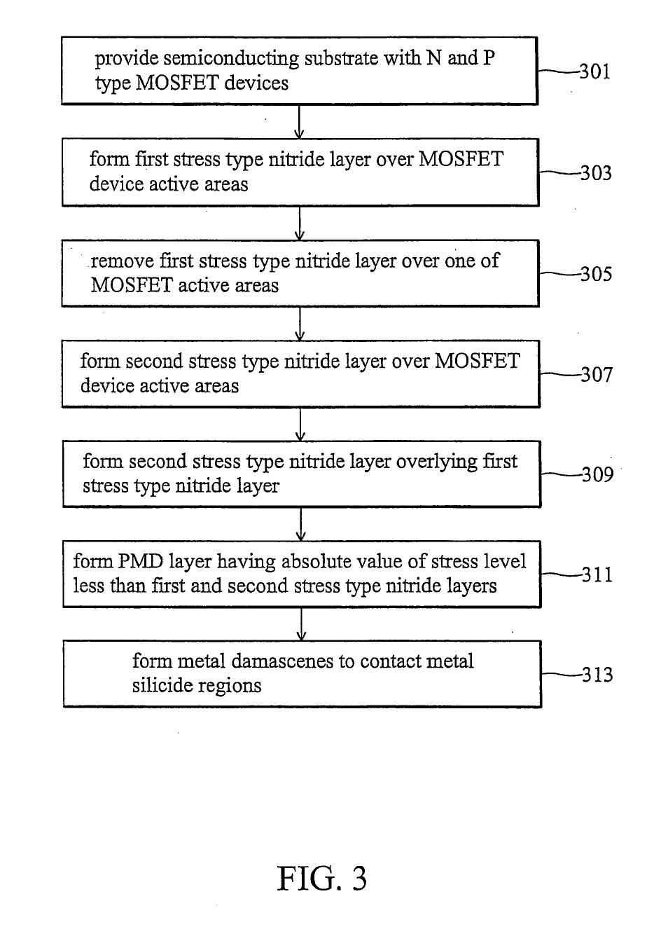

FIG. 3 is an exemplary process flow diagram including several embodiments of the present invention.

### DETAILED DESCRIPTION OF THE PREFERRED EMBODIMENTS

Although the method of the present invention is explained with reference to exemplary NMOS and PMOS MOSFET devices, it will be appreciated that the method of the present invention may be applied to the formation of any MOSFET device where a strain is controllably introduced into a charge carrier channel region by selective formation of stressed dielectric layers overlying the respective NMOS and/or PMOS device regions with subsequent preferred PMD layer formation.

Referring to FIGS. 1A-1F in an exemplary embodiment of the method of the present invention, are shown cross-sectional schematic views of a portion of a semiconductor wafer during stages in production of MOSFET structures including NMOS and PMOS devices 10A and 10B. For example, referring to FIG. 1A, is shown a semiconductor substrate 12, which may include silicon, strained semiconductor, compound semiconductor, multi-layered semiconductors, silicon on strained semiconductor, silicon on insulator, and combinations thereof. For example, the substrate 12 may include, but is not limited to, silicon on insulator (SOI), stacked SOI (SSOI), stacked SiGe on insulator (S—SiGeOI), SiGeOI, and GeOI, or combinations thereof. It will be appreciated that the semiconducting substrate may be formed to have buried channel regions. The semiconducting substrate may includes doped well regions 12A and 12B making up respective PMOS and NMOS device regions formed by conventional methods, for example a masking process followed by ion implantation and activation annealing. Electrical isolation regions, preferably (STI) structures e.g., 14A, 14B, and 14C, back filled with an oxide dielectric, for example, TEOS oxide or HDP-CVD oxide, are formed by conventional processes.

Still referring to FIG. 1A, gate structures are formed by conventional processes including gate dielectric portions e.g., 16A and 16B and overlying gate electrode portions e.g., PMOS device gate electrode 18A and NMOS device gate electrode 18B. For example, gate dielectric layers and gate electrode layers are deposited by CVD processes followed by photolithographic patterning and plasma assisted etching (e.g., RIE) to form the respective PMOS and NMOS gate structures.

The gate dielectric portions e.g., 16A and 16B may be formed of silicon oxide, silicon oxynitride, silicon nitride, nitrogen doped silicon oxide, high-K dielectrics, or combinations thereof. The high-K dielectrics may include metal oxides, metal silicates, metal nitrides, transition metal-oxides, transition metal silicates, metal aluminates, and transition metal nitrides, or combinations thereof. The gate dielectric portions e.g., 16A and 16B may be formed by any process known in the art, e.g., thermal oxidation, nitridation, sputter deposition, or chemical vapor deposition. When using a high permittivity (high-K) gate dielectric, the dielectric constant is preferably greater than about 8. For example, the high-K dielectric may be include one or more of aluminum oxide (e.g., Al₂O₃), hafnium oxide (e.g., HfO₂), hafnium oxynitride (e.g., HfON), hafnium silicate (e.g., HfSiO₄), zirconium oxide (e.g., ZrO₂), zirconium oxynitride (e.g., ZrON), zirconium silicate (e.g., ZrSiO₂), yttrium oxide (e.g., Y₂O₃), lanthanum oxide (e.g., La₂O₃), cerium oxide (e.g., CeO₂), titanium oxide (e.g., TiO₂), tantalum oxide (e.g., Ta₂O₅), or combinations thereof.

The gate electrode portions e.g., 18A and 18B may be formed of polysilicon, polysilicon-germanium, metals, metal silicides, metal nitrides, or conductive metal oxides. In a preferred embodiment, the gate electrodes are formed of polysilicon. Metals silicides as explained below are preferably formed be used in an upper portion of the gate electrodes e.g., 16A, 16B to form conductive contact regions. In a preferred embodiment, the contact regions are formed of metal silicides including cobalt silicide (e.g., CoSi₂) or nickel silicide (e.g., NiSi), as the method of the present invention which includes forming a stressed nitride contact etch stop layer by a mixed frequency PECVD process as explained below overcomes processing difficulties of the prior art in using these metal silicide materials, particularly NiSi.

Following formation of the gate electrodes, source/drain extension (SDE) regions e.g., 20A and 20B on either side of a channel region are formed by a conventional ion implant process adjacent the gate structures beneath the silicon substrate surface according to a low energy ion implantation. It will be appreciated that offset spacer liner layers e.g., 21A, 21B, of silicon oxide, silicon nitride, or silicon oxynitride may be formed adjacent the gate structures prior to or following formation of the SDE regions.

Still referring to FIG. 1A, sidewall spacers e.g., 22A and 22B, are formed on either side of the gate structures by conventional processes including depositing one or more layers of silicon nitride (e.g., Si₃N₄), silicon oxynitride (e.g., SiON), and silicon oxide (e.g., SiO₂), followed by etching away portions of the one or more layers to form self-aligned sidewall spacers on either side of the gate structures.

Following sidewall spacer formation, the NMOS and PMOS device areas are sequentially doped according to a conventional high dose ion implantation (HDI) process to form the high density implant portions of doped source/drain (S/D) regions e.g., 20C and 20D in the substrate 12 adjacent the sidewall spacers.

Still referring to FIG. 1A, metal silicide portions e.g., 24A and 214B 24C and 24D are preferably formed overlying the source and drain regions 20C and 20D and over the upper portion of the gate electrodes e.g., 18A and 18B. As previously noted, the metal silicide portions are preferably formed of CoSi₂ or NiSi, or combinations thereof by known processes.

Referring to FIG. 1B, according to an important aspect of the invention, a compressive or tensile stressed dielectric layer 30A is deposited over the substrate surface including both NMOS and PMOS active device regions, a respective active device region for example including overlying respective well regions e.g., 12A and 12B. In an important aspect of the invention, the stressed dielectric layer e.g., 30A is a nitride layer, preferably formed of one or more of silicon nitride (e.g., SiN) and silicon oxynitride (e.g., SiON), by a mixed frequency method using a PECVD reactor equipped for generating mixed frequency RF source power for selectively forming a desired compressive or tensile stress level of stressed nitride layer e.g., 30A.

For example, referring briefly to FIG. 2 is shown an exemplary mixed frequency PECVD reactor for forming the stressed dielectric layers according to an aspect of the invention. The mixed frequency PECVD reactor includes a conventional plasma chamber 42, a wafer support 44 for mounting semiconductor process wafer substrate 45, preferably equipped with a means for heating the process wafer, e.g., resistive heating elements (not shown). The process wafer 45 and the wafer support 44 are preferably at relative electrical ground to the RF source power which may include a DC bias.

Conventional reactive gas (plasma source gas) feeds, e.g., 46, a gas dispersion showerhead e.g., 48, and dielectric window (not shown) are provided in an upper portion of the plasma chamber 42. The mixed frequency PECVD reactor is preferably provided with a dual frequency RF source power generators e.g., 50A and 50B, one RF power source e.g., 50A a low frequency power source for generating RF power at a frequency of about 300 to about 500 KHz and a high frequency power source e.g., 50B for generating RF power at a frequency of about 13.56 MHz for generating a mixed frequency RF power signal, e.g., through frequency mixer 50C, which is coupled to plasma chamber 42 for generating a plasma.

For example, the mixed frequency PECVD deposition method includes supplying a precursor such as silane (SiH4), NH₃, and N2 at a deposition temperature of from about 300° C. to about 600° C., more preferably less than about 550° C. at pressures of from about 2 Torr to about 5 Torr and mixed frequency RF powers of from about 100 Watts to about 1000 Watts. It will be appreciated other silane precursors or silane precursor mixtures alternatively or in addition to silane (SiH4) may be used such as disilane (Si₂H₆), trisilane (Si₃H₈), dichlorosilane (SiH₂Cl₂), trichlorosilane (SiHCl₃), and the like.

It will be appreciated that the level of stress can be varied by a number of factors, the most important being the mixed frequency signal including the frequency of the lower frequency RF power source to produce a mixed frequency RF source component. For example, the compressive stress of the stressed nitride layers increases with increasing power and low frequency component of the mixed frequency RF power signal. Other factors, such as the thickness of the stressed dielectric layer, for example from about 100 Angstroms to about 1000 Angstroms, more preferably from about 100 Angstroms to about 700 Angstroms in thickness, can also be varied to achieve a desired stress level. In addition, the relative reactant flow rates, deposition pressure, and temperature may be varied to alter the composition of the dielectric layer thereby further selectively producing a desired stress level. Advantageously, by using a mixed frequency method to produce the stressed nitride layer 30A, a single deposition tool may be advantageously used to achieve both tensile and compressive stress films as explained below.

Preferably the stressed nitride layer 30A is formed with a compressive or tensile stress level (absolute value) greater than about 7×10^{ˆ9} dynes/cm². It will be appreciated that a tensile stress level is represented by a positive value and a compressive stress represented by a negative value.

Referring to FIG. 1C, the stressed dielectric layer 30A is then preferably selectively removed over one of the MOSFET devices depending on the stress type e.g., tensile or compressive of the stressed nitride layer e.g., 30A. For example, the stressed nitride layer (e.g., tensile) is removed a second MOSFET device of opposite polarity (e.g., P type)compared to a first MOSFET device (e.g., N-type) where the second MOSFET device drive current is either degraded or not improved by the stress type (e.g., tensile) of the first stressed nitride layer 30A. For example, a tensile stressed nitride layer e.g., 30A produces a strained channel region e.g., 31B improving charge carrier mobility of NMOS device e.g., 18B while a compressive stressed nitride layer e.g., 30A produces a strained channel region e.g., 31A improving charge carrier mobility of a PMOS device e.g., 18A. For example, if the stressed nitride layer 30A is formed in tensile stress, a resist patterning process is carried out to form patterned resist portions e.g., 32 covering NMOS device active region 12B portion while leaving uncovered PMOS device region 12A, followed by a wet or dry, preferably dry etching process to strip off the tensile stressed nitride layer e.g., 30A over the PMOS device region.

Referring to FIG. 1D, in another embodiment, following removing resist layer portion 32, optionally but preferably, a second stressed nitride 30B is formed over both PMOS and NMOS active device regions according to the same preferred embodiments as for the first stressed nitride layer 30A, but in opposite stress relationship, e.g., compressive to form a compressive stress dielectric layer overlying active regions 12A and 12B.

Referring to FIG. 1E, following formation of the second stressed nitride layer 30B, a similar photolithographic patterning and stripping process is carried out to remove the portion of compressive stressed nitride layer 30B overlying the NMOS device region 12B. It will be appreciated that a similar series of process steps may be carried out by first depositing a compressive stressed nitride layer over both PMOS and NMOS active device regions, removing the compressive stress layer portion over the NMOS active device region, forming a tensile stress nitride layer over both the NMOS and PMOS active device regions, followed by removing the tensile stressed nitride layer portion overlying the PMOS active device region to finally leave a compressive stressed nitride layer overlying the PMOS device region and a tensile stressed nitride layer overlying the NMOS device region. It will also be appreciated that the second stressed nitride layer e.g., 30B may optionally not be formed following removal of first stressed nitride layer e.g., 30A.

Referring to FIG. 1F, following formation of the stressed nitride layers 30A and 30B, a PMD layer 34, also sometimes referred to as an ILD layer, is preferably formed overlying the NMOS and PMOS device active regions preferably having a less compressive or tensile stress. Preferably the PMD layer 34 is formed of undoped silicate glass (USG), phosphosilicate glass (PSG) by an atmospheric (AP) or sub-atmospheric (SA) pressure CVD process. Alternatively the PMOS layer 34 is preferably formed by undoped or P-doped spin-on glass (SOG) by a spin on process. It has been found that PMD layer formation methods of the prior art e.g., high sputtering rate HDP-CVD methods reduce the effectiveness of the stressed nitride layers by either stress relaxation by thinning the stressed nitride layers as well as producing offsetting stresses in the PMD layer.

Advantageously, by avoiding a high sputter rate HDP-CVD process, thinning of the stressed nitride layers is avoided thereby preserving the stress type and level formed in the stressed nitride layers e.g., 30A and 30B. Following deposition of the PMD layer conventional steps such as CMP planarization step and conventional photolithographic patterning and etching processes are carried out to form metal filled contacts e.g., 36A, 36B, 36C to form electric contact wiring to the source/drain and/or gate electrode metal salicide regions. Advantageously, deterioration of metal silicide regions, especially NiSi is avoided compared to prior art processes by forming the stressed nitride layers e.g., 30A and 30B at temperatures less than about 550° C.

Thus, a method has been presented for improving NMOS and PMOS device performance by selectively forming stressed nitride layers of a desired type over NMOS and PMOS devices to introduce strain into a MOSFET device channel region. By using a mixed frequency PECVD deposition method, a wider range of stress levels may be more precisely achieved as well as forming nitride layers with either type of stress, e.g., compressive or tensile. In addition, step coverage is improved by the mixed frequency method of formation of stressed nitride layers. Moreover, the lower deposition temperatures by the mixed frequency PECVD process required to achieve a desired stress level compared to prior art deposition processes avoids detrimental deterioration of NiSi or CoSi₂ resistivity. Preferred formation of the PMD layer avoids stress relaxation or diminishing of the stress levels of the stressed nitride layers.

Device performance has been demonstrably improved. For example, MOSFET devices with CoSi₂ or NiSi metal silicides with the formation of stressed nitride layers of greater than about 7×10⁹ dynes/cm² have shown an improvement of about 2.5% to about 6.5% improvement in drive current (I_{dsat}-I_{off}) compared to prior art single frequency PECVD deposition methods. Additionally, formation of the PMD layer according to preferred embodiments, further improves drive current without accompany drive current degradation effects for opposite polarity devices.

Referring to FIG. 3 is a process flow diagram including several embodiments of the present invention. In process 301, a semiconductor substrate including respective MOSFET devices of a first and second polarity (e.g., N and P type) formed over respective active device regions is provided. In process 303 a first stressed nitride layer of a first stress type (e.g., tensile or compressive) is formed over the MOSFET device active regions according to preferred embodiments. In process 305, the first stressed nitride layer is removed over one of the (e.g. second) polarity MOSFET device regions. In process 307, a second stressed nitride layer of a second stress type is formed over the MOSFET device active regions. In process 309, the second stress type nitride layer is removed overlying the remaining portion of the first stress type nitride layer to leave a compressive stress nitride layer overlying a P type MOSFET device active area and a tensile stress nitride layer overlying an N type MOSFET device active area. In process 311, a PMD layer is formed over the MOSFET device regions according to preferred embodiments having a less compressive or tensile stress. In process 313, metal contacts are formed to the respective MOSFET device metal silicide regions.

The preferred embodiments, aspects, and features of the invention having been described, it will be apparent to those skilled in the art that numerous variations, modifications, and substitutions may be made without departing from the spirit of the invention as disclosed and further claimed below.

What is claimed is:

1. A method for introducing strain into a MOSFET channel region comprising the steps of:
providing a first and second MOSFET device having a respective first polarity and second polarity opposite from the first polarity selected from the group consisting of P and N type on a semiconducting substrate;
forming a first stressed nitride layer having a first stress type selected from the group consisting of compressive and tensile stress over the first and second MOSFET device active areas;
removing the first stressed nitride layer overlying the second MOSFET device active area;
forming a second stressed nitride layer having a second stress type opposite the first stress type over the first and second MOSFET device active areas;
removing the second stressed nitride layer overlying the first MOSFET device active area; and,
forming a dielectric insulating layer over the first and second MOSFET device active areas having a less compressive or tensile stress.

2. The method of claim 1, wherein the first and second stressed nitride layers are formed by a mixed frequency PECVD method.

3. The method of claim 2, wherein the mixed frequency PECVD method comprises at least two RF power sources to produce a mixed frequency signal, a first RF power source operating at a frequency of from about 300 KHz to 500 KHz and a second RF power source operating at a frequency of about 13 to 14 MHz.

4. The method of claim 1, wherein the first and second MOSFET devices further comprise metal silicide regions selected from the group consisting of cobalt silicide and nickel silicide.

5. The method of claim 1, wherein the first and second stressed nitride layers are formed at a temperature of less than about 550° C.

6. The method of claim 1, wherein first and second stressed layers are selected from the group consisting of silicon nitride and silicon oxynitride.

7. The method of claim 1, wherein the dielectric insulating layer is selected from the group consisting of undoped silicate (USG) glass and phosphorous silicate glass (PSG) deposited according to a CVD method selected from the group consisting of atmospheric and sub-atmospheric CVD.

8. The method of claim 1, wherein the dielectric insulating layer is selected from the group consisting of undoped and P-doped spin-on glass (SOG).

9. The method of claim 1, wherein the stressed nitride layers are formed comprising silane containing precursors selected from the group consisting of (SiH₄), disilane (Si₂H₆), trisilane (Si₃H₈), dichlorosilane (SiH₂Cl₂), trichlorosilane (SiHCl₃), and hexacholorodisilane (HCD)(Si₂Cl₆).

10. The method of claim 1, wherein the stressed nitride layers are formed having a stress level absolute value greater than about 7×10⁹ dynes/cm².

11. The method of claim 1, wherein the semiconductor substrate comprises a material selected from the group consisting of silicon, strained semiconductor, compound semiconductor, multi-layered semiconductors, silicon on strained semiconductor, silicon on insulator, and combinations thereof.

12. The method of claim 1, wherein the semiconductor substrate comprises silicon on insulator (SOI), stacked SOI (SSOI), stacked SiGe on insulator (S—SiGeOI), SiGeOI, and GeOI, and combinations thereof.

13. The method of claim 1, wherein the stressed nitride layers are formed having a thickness from about 100 Angstroms to about 1000 Angstroms.

14. A method for forming a contact etch stop layer and overlying PMD layer for selectively introducing strain into a MOSFET channel region comprising the steps of:
providing a first and second MOSFET device having a respective first polarity and second polarity opposite from the first polarity selected from the group consisting of P and N type on a semiconducting substrate;
forming a first stressed nitride contact etch stop (CESL) layer according to a mixed frequency PECVD method having a first stress type selected from the group consisting of compressive and tensile stress over the first and second MOSFET device active area;
removing a portion of the first stressed nitride CESL layer portion overlying the second MOSFET device active area;
forming a second stressed nitride CESL layer having a second stress type according to a mixed frequency PECVD method opposite the first stressed nitride layer over the first and second MOSFET device active areas;
removing a portion of the second stressed nitride CESL layer overlying the first MOSFET device active area; and,
forming a pre-metal dielectric (PMD) layer over the first and second MOSFET device active areas having a less compressive or tensile stress.

15. The method of claim 14, wherein the mixed frequency PECVD method comprises at least two RF power sources to produce a mixed frequency signal, a first RF power source operating at a frequency of from about 300 KHz to 500 KHz and a second RF power source operating at a frequency of about 13 to 14 MHz.

16. The method of claim 14, wherein the first and second MOSFET devices further comprise metal silicide regions selected from the group consisting of cobalt silicide and nickel silicide.

17. The method of claim 14, wherein the first and second stressed nitride CESL layers are formed at a temperature of less than about 550° C.

18. The method of claim 14, wherein first and second stressed CESL layers are selected from the group consisting of silicon nitride and silicon oxynitride.

19. The method of claim 14, wherein the PMD layer is selected from the group consisting of undoped silicate (USG) glass and phosphorous silicate glass (PSG) deposited according to a CVD method selected from the group consisting of atmospheric and sub-atmospheric CVD.

20. The method of claim 14, wherein the PMD layer is selected from the group consisting of undoped and P-doped spin-on glass (SOG).

21. The method of claim 14, wherein the stressed nitride CESL layers are formed comprising silane containing precursors selected from the group consisting of (SiH₄), disilane (Si₂H₆), trisilane (Si₃H₈), dichlorosilane (SiH₂Cl₂), trichlorosilane (SiHCl₃), and hexacholorodisilane (HCD)(Si₂Cl₆).

22. The method of claim 14, wherein the stressed nitride CESL layers are formed having a stress level absolute value greater than about 7×10⁹ dynes/cm².

23. The method of claim 14, wherein the semiconductor substrate comprises a material selected from the group consisting of silicon, strained semiconductor, compound semiconductor, multi-layered semiconductors, silicon on strained semiconductor, silicon on insulator, and combinations thereof.

24. The method of claim 14, wherein the semiconductor substrate comprises silicon on insulator (SOI), stacked SOI (SSOI), stacked SiGe on insulator (S—SiGeOI), SiGeOI, and GeOI, and combinations thereof.

25. The method of claim 14, wherein the stressed nitride layers are formed having a thickness from about 100 Angstroms to about 1000 Angstroms.

26. A MOSFET device pair with improved drive current comprising:
an N-type polarity MOSFET device and a P-type polarity MOSFET device disposed over respective active areas on a semiconductor substrate;
a first stressed nitride layer having a tensile stress over the N-type polarity MOSFET device active area;
a second stressed nitride layer having a compressive stress over the P-type polarity MOSFET device active area; and,
a dielectric insulating layer overlying the respective MOSFET device active areas having a less compressive or tensile stress.

27. The MOSFET device pair of claim 26, wherein the first and second MOSFET devices further comprise metal silicide regions selected from the group consisting of cobalt silicide and nickel silicide.

28. The MOSFET device pair of claim 26, wherein first and second stressed layers are selected from the group consisting of silicon nitride and silicon oxynitride.

29. The MOSFET device pair of claim 26, wherein the dielectric insulating layer is selected from the group consisting of undoped silicate (USG) glass and phosphorous silicate glass (PSG).

30. The MOSFET device pair of claim 26, wherein the dielectric insulating layer is selected from the group consisting of undoped and P-doped spin-on glass (SOG).

31. The MOSFET device pair of claim 26, wherein the stressed nitride layers are formed having a stress level absolute value greater than about 7×10⁹ dynes/cm².

32. The MOSFET device pair of claim 26, wherein the semiconductor substrate comprises a material selected from the group consisting of silicon, strained semiconductor, compound semiconductor, multi-layered semiconductors, silicon on strained semiconductor, silicon on insulator, and combinations thereof.

33. The MOSFET device pair of claim 26, wherein the semiconductor substrate comprises silicon on insulator (SOI), stacked SOI (SSOI), stacked SiGe on insulator (S—SiGeOI), SiGeOI, and GeOI, and combinations thereof.

34. The MOSFET device pair of claim 26, wherein the stressed nitride layers are formed having a thickness from about 100 Angstroms to about 1000 Angstroms.
